(19) United States
(12) Patent Application Publication
(10) Pub. No.: US 2008/0003783 A1
(43) Pub. Date: Jan. 3, 2008

(54) METHOD OF REDUCING A ROUGHNESS OF A SEMICONDUCTOR SURFACE

(76) Inventors: Andy Wei, Dresden (DE); Thorsten Kammler, Ottendorf-Okrilla (DE); Jan Hoentschel, Dresden (DE); Manfred Horstmann, Duerrrhoehrsdorf-Dittersbach (DE)

Correspondence Address: WILLIAMS, MORGAN & AMERSON, 10333 RICHMOND, SUITE 1100, HOUSTON, TX, 77042, US

(21) Appl. No.: 11/624,276

(22) Filed: Jan. 18, 2007

(30) Foreign Application Priority Data
Jun. 30, 2006 (DE) 10 2006 030 268.0

(51) Int. Cl. H01L 21/36

(52) U.S. Cl. 438/478; 438/770; 438/771; 438/697

(57) ABSTRACT

A method of smoothening a surface of a semiconductor structure comprises exposing the surface of the semiconductor structure to a reactant. A chemical reaction between a material of the semiconductor structure and the reactant is performed. In the chemical reaction, a layer of a reaction product is formed on at least a portion of the surface of the semiconductor structure. The layer of the reaction product is selectively and completely removed.

### BACKGROUND OF THE INVENTION

1. Field of the Invention

The present disclosure generally relates to the formation of integrated circuits, and, more particularly, to the smoothening of a surface of a semiconductor structure.

2. Description of the Related Art

Integrated circuits comprise a large number of individual circuit elements, such as transistors, capacitors and resistors. These elements are connected internally to form complex circuits, such as memory devices, logic devices and microprocessors. The performance of integrated circuits can be improved by increasing the number of functional elements in the circuit in order to increase their functionality and/or by increasing the speed of operation of the circuit elements. A reduction of feature sizes allows the formation of a greater number of circuit elements on the same area, hence allowing an extension of the functionality of the circuit, and also reduces signal propagation delays, thus making an increase of the speed of operation of circuit elements possible.

Field effect transistors are used as switching elements in integrated circuits. They provide a means to control a current flowing through a channel region located between a source region and a drain region. The source region and the drain region are highly doped. In N-type transistors, the source and drain regions are doped with an N-type dopant. Conversely, in P-type transistors, the source and drain regions are doped with a P-type dopant. The doping of the channel region is inverse to the doping of the source region and the drain region. The conductivity of the channel region is controlled by a gate voltage applied to a gate electrode formed above the channel region and separated therefrom by a thin insulating layer. Depending on the gate voltage, the channel region may be switched between a conductive “on” state and a substantially non-conductive “off” state.

When reducing the size of field effect transistors, it is important to maintain a high conductivity of the channel region in the “on” state. The conductivity of the channel region in the “on” state depends on the dopant concentration in the channel region, the mobility of the charge carriers, the extension of the channel region in the width direction of the transistor and on the distance between the source region and the drain region, which is commonly denoted as “channel length.” While a reduction of the width of the channel region leads to a decrease of the channel conductivity, a reduction of the channel length enhances the channel conductivity. An increase of the charge carrier mobility leads to an increase of the channel conductivity.

As feature sizes are reduced, the extension of the channel region in the width direction is also reduced. A reduction of the channel length entails a plurality of issues associated therewith. First, advanced techniques of photolithography and etching have to be provided in order to reliably and reproducibly create transistors having short channel lengths. Moreover, highly sophisticated dopant profiles, in the vertical direction as well as in the lateral direction, are required in the source region and in the drain region in order to provide a low sheet resistivity and a low contact resistivity in combination with a desired channel controllability.

In view of the problems associated with a further reduction of the channel length, it has been proposed to also enhance the performance of field effect transistors by increasing the charge carrier mobility in the channel region. In principle, at least two approaches may be used to increase the charge carrier mobility.

First, the dopant concentration in the channel region may be reduced. Thus, the probability of scattering events of charge carriers in the channel region is reduced, which leads to an increase of the conductivity of the channel region. Reducing the dopant concentration in the channel region, however, significantly affects the threshold voltage of the transistor device. This makes the reduction of dopant concentration a less attractive approach.

Second, the lattice structure in the channel region may be modified by creating tensile or compressive strain. This leads to a modified mobility of electrons and holes, respectively. Depending on the magnitude of the strain, a compressive strain may significantly increase the mobility of holes in a silicon layer, and may also increase the electron mobility. The mobility of electrons may also be increased by providing a silicon layer having a tensile strain.

A method of forming a field effect transistor wherein the channel region is formed in strained silicon will be described in the following with reference to FIGS. 1a-1d. FIG. 1a shows a schematic cross-sectional view of a semiconductor structure 100 in a first stage of a manufacturing process according to the state of the art. The semiconductor structure 100 comprises a substrate 101. In the substrate 101, an active region 104 is provided. Shallow trench isolations 102, 103, which may be part of one continuous trench isolation structure, separate the active region 104 from other elements of the semiconductor structure 100 which are not shown in FIG. 1a. A gate electrode 106, which is separated from the substrate 101 by a gate insulation layer 105, is formed over the substrate 101. The gate electrode 106 is covered by a cap layer 107 and flanked by first sidewall spacers 108, 109. The active region 104, the shallow trench isolations 102, 103, the gate electrode 106, the gate insulation layer 105, as well as the first sidewall spacers 108, 109 and the cap layer 107, together form portions of a transistor element 130.

In the formation of the semiconductor structure 100, the substrate 101 is provided and the shallow trench isolations 102, 103 are formed by means of methods of photolithography, deposition and/or oxidation known to persons skilled in the art. Then, ions of a dopant material are implanted into the substrate 101 in order to form the active region 104. The type of dopants corresponds to the doping of the channel region of the field effect transistor to be formed. Hence, in the formation of an N-type transistor, ions of a P-type dopant are implanted, whereas ions of an N-type dopant are implanted in the formation of a P-type transistor.

After the formation of the active region 104, an oxidation process is performed to form the gate insulation layer 105. Thereafter, the gate electrode 106 and the cap layer 107 are formed by processes of deposition and photolithography known to persons skilled in the art. Subsequently, the first sidewall spacers 108, 109 are formed by isotropically depositing a layer of a spacer material and performing an anisotropic etch process, wherein portions of the layer of spacer material over substantially horizontal portions of the semiconductor structure 100 are removed, whereas portions of the layer of spacer material provided on the flanks of the gate electrode 106 remain on the substrate 101 and form the first sidewall spacers 108, 109.

A schematic cross-sectional view of the semiconductor structure 100 in a later stage of the manufacturing process according to the state of the art is shown in FIG. 1b. A first etch process is performed. The first etch process can be an isotropic etch process adapted to selectively remove the material of the substrate 101, leaving the material of the cap layer 107 and the first sidewall spacers 108, 109 substantially intact, for example a known dry etch process. The cap layer 107 and the first sidewall spacers 108, 109 protect the gate electrode 106, the gate insulation layer 105 and a channel region 140 below the gate electrode 106 from being affected by an etchant used in the first etch process.

Portions of the substrate 101 adjacent the gate electrode 106, however, are etched away. Thus, a source side cavity 110 and a drain side cavity 111 are formed adjacent the gate electrode 106. Due to the isotropy of the etch process, portions of the substrate 101 below the first sidewall spacers 108, 109 and, optionally, also the gate electrode 106 are removed. Therefore, the cavities 110, 111 may extend below the sidewall spacers 108, 109 and/or the gate electrode 106, the surface of the cavities 110, 111 having a somewhat rounded shape.

After the first etch process, the cavities 110, 111 may have a rough surface. Reference numerals 112, 113 schematically indicate unevenness of the surface of the cavities 110, 111. If a stress-creating material were deposited over the substrate 101 in order to fill the cavities 110, 111 as described below, the unevenness 112, 113 would act as nucleation sites, leading to an undesirable polycrystalline growth of the stress-creating material. Therefore, a smoothening process is performed in order to reduce the number and size of unevenness 112, 113 of the surface.

FIG. 1c shows a schematic cross-sectional view of the semiconductor structure 100 in yet another stage of the manufacturing process. In methods of forming a field effect transistor according to the state of the art, the surface of the cavities 110, 111 may be smoothened by means of a high temperature pre-bake process. In the high temperature pre-bake process, the semiconductor structure 100 is exposed to a temperature in a range from about 800-1000° C. for about 30 seconds to about 10 minutes. During the pre-bake process, the semiconductor structure 100 can be provided in an ambient comprising hydrogen gas which substantially does not react chemically with the materials of the semiconductor structure 100.

During the pre-bake process, atoms of the material of the substrate 101 may diffuse on the surface of the cavities 110, 111. Due to the diffusion, the atoms may reach locations where they are chemically bound in an energetically favorable manner. Thus, in the pre-bake process, the atoms may re-arrange in an energetically more favorable configuration. Since a relatively smooth surface comprises a smaller number of atoms which are located at energetically unfavorable lattice sites, the surface roughness of the substrate 101 in the cavities 110, 111 is reduced during the pre-bake process.

The re-arrangement of atoms in the pre-bake process, however, may also lead to a reduction of the depth of the cavities 110, 111 in the vicinity of the gate electrode 106, as shown in FIG. 1c, since such re-arrangement leads to a reduction of the curvature of the surface of the substrate 101 in the cavities 110, 111 which entails an energetically favorable reduction of the surface energy. Thus, portions of the cavities 110, 111 in the vicinity of the gate electrode 106, in particular portions of the cavities 110, 111 extending below the first sidewall spacers 108, 109 and/or the gate electrode 106, may be filled with material of the substrate 101.

Strain-creating elements 114, 115 are formed adjacent the gate electrode 106. To this end, the cavities 110, 111 are filled with a strain-creating material. In methods of forming a field effect transistor according to the state of the art, the strain-creating material may comprise silicon germanide. As persons skilled in the art know, silicon germanide is an alloy of silicon (Si) and germanium (Ge). Other materials may be employed as well.

Silicon germanide is a semiconductor material having a greater lattice constant than silicon. When silicon germanide is deposited in the cavities 110, 111, however, the silicon and germanium atoms in the strain-creating elements 114, 115 tend to adapt to the lattice constant of the silicon in the substrate 101. Therefore, the lattice constant of the silicon germanide in the strain-creating elements 114, 115 is smaller than the lattice constant of a bulk silicon germanide crystal. Thus, the material of the strain-creating elements 114, 115 is compressively strained.

The strain-creating elements 114, 115 can be formed by means of selective epitaxial growth. As persons skilled in the art know, selective epitaxial growth is a variant of plasma-enhanced chemical vapor deposition wherein parameters of the deposition process are adapted such that material is deposited only on the surface of the substrate 101 in the cavities 110, 111, whereas substantially no material deposition occurs on the surface of the first sidewall spacers 108, 109 and the cap layer 107.

Since the strain-creating elements 114, 115 are compressively strained, they exhibit a force to portions of the substrate 101 in the vicinity of the gate electrode 106, in particular to portions of the substrate 101 in the channel region 140. Therefore, a compressive strain is created in the channel region 140.

FIG. 1d shows a schematic cross-sectional view of the semiconductor structure 100 in yet another stage of the manufacturing process according to the state of the art. After the formation of the strain-creating elements 114, 115, the first sidewall spacers 108, 109 are removed. Additionally, the cap layer 107 may be removed. Thereafter, an extended source region 116 and an extended drain region 117 are formed in portions of the substrate 101 and the strain-creating elements 114, 115 by means of an ion implantation process known to persons skilled in the art. In the ion implantation process, ions of a dopant material are introduced into the substrate 101 and the strain-creating elements 114, 115. In case of the formation of an N-type field effect transistor, ions of an N-type dopant are introduced, wherein ions of a P-type dopant are provided in the formation of a P-type transistor.

Subsequently, second sidewall spacers 118, 119 are formed adjacent the gate electrode 106. Thereafter, a further ion implantation process is performed to form a source region 120 and a drain region 121 by introducing dopant material ions. Finally, an annealing process may be performed to activate the dopant materials introduced in the formation of the extended source region 116, the extended drain region 117, the source region 120 and the drain region 121.

One problem associated with the above method of forming a field effect transistor according to the state of the art is that the strain created by the strain-creating elements 114, 115 may be insufficiently transmitted to the channel region 140. This may lead to a reduced enhancement of the mobility of holes and/or electrons in the channel region.

The present disclosure is directed to various methods that may solve, or at least reduce, some or all of the aforementioned problems.

### SUMMARY OF THE INVENTION

The following presents a simplified summary of the disclosed subject matter in order to provide a basic understanding of some aspects of the subject matter disclosed herein. This summary is not an exhaustive overview of the technology disclosed herein. It is not intended to identify key or critical elements of the invention or to delineate the scope of the invention. Its sole purpose is to present some concepts in a simplified form as a prelude to the more detailed description that is discussed later.

According to an illustrative embodiment disclosed herein, a method of reducing the roughness of a surface of a semiconductor structure comprises exposing the surface of the semiconductor structure to a reactant. A chemical reaction between a material of the semi-conductor structure and the reactant is performed. In the chemical reaction, a layer of a reaction product is formed on at least a portion of the surface of the semiconductor structure. The layer of the reaction product is selectively and completely removed. A selective epitaxial growth process is performed to deposit a material layer over at least a portion of the semiconductor structure.

According to another illustrative embodiment, a method of forming a semiconductor structure comprises forming a feature on a surface of a substrate. A first etching process adapted to selectively remove a material of the substrate and to leave the feature substantially intact is performed. After the first etching process, the semiconductor structure is exposed to a reactant and a chemical reaction between the material of the substrate and the reactant is performed, a layer of a reaction product being formed on at least a portion of the substrate. A second etching process adapted to selectively remove the layer of reaction product and to leave the feature and the material of the substrate substantially intact is performed.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d show schematic cross-sectional views of a semiconductor structure in stages of a manufacturing process according to the state of the art; and

FIGS. 2a-2c show schematic cross-sectional views of a semiconductor structure in stages of a manufacturing process in accordance with illustrative embodiments disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the subject matter disclosed herein. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The subject matter disclosed herein is generally based on the realization that an insufficient transmission of strain created by the strain-creating elements 114, 115 may be caused by the shape of the cavities 110, 111 obtained after the high temperature pre-bake performed in order to reduce the roughness of the surface of the substrate 101 in the cavities 110, 111. As detailed above, in the pre-bake process, semiconductor material may be deposited in portions of the cavities 110, 111 adjacent the gate electrode 106 such that the depth of the cavities 110, 111 can be reduced in the vicinity of the gate electrode 106 and portions of the cavities 110, 111 extending below the first sidewall spacers 108, 109 and/or the gate electrode 106 may be filled with semiconductor material. Therefore, the strain-creating elements 114, 115 are positioned at a greater distance to the gate electrode 106. The cavities 110, 111 may also have a reduced depth in the vicinity of the gate electrode 106. Thus, the effectiveness of the creation of strain and the depth of the strained region below the gate electrode 106 can be increased.

The subject matter disclosed herein provides methods for reducing the roughness of the surface of a semiconductor structure and wherein an alteration of the shape of cavities may be reduced. Thus, strain-creating elements may be provided more closely to the channel region of a field effect transistor and a depth of the strain-creating elements in the vicinity of the channel region may be retained substantially unaltered. The present invention, however, is not restricted to embodiments wherein a field effect transistor comprising strain-creating elements and/or a strained channel region is formed. Instead, methods according to the present invention may be used in a variety of applications wherein it is desirable to reduce the roughness of a surface of a semiconductor structure.

In methods of reducing the roughness of a surface of a semiconductor structure according to embodiments disclosed herein, a chemical reaction between a reactant and a material of the semiconductor structure is performed. In the chemical reaction, a layer of a reaction product is formed on the surface of the semiconductor structure. Thereafter, the layer of reaction product is removed.

During the chemical reaction, the reactant diffuses through the forming layer of reaction product into the semiconductor structure. In the diffusion process, the reactant is distributed over the interface between the layer of reaction product and the semiconductor structure. Thus, an influence of the roughness of the surface of the semiconductor structure on the further growth of the layer of reaction product may be reduced, which may lead to a relatively smooth interface between the layer of reaction product and the semiconductor structure. The shape of the interface may be substantially preserved when the layer of reaction product is removed. Therefore, a relatively smooth surface of the semiconductor structure can be obtained.

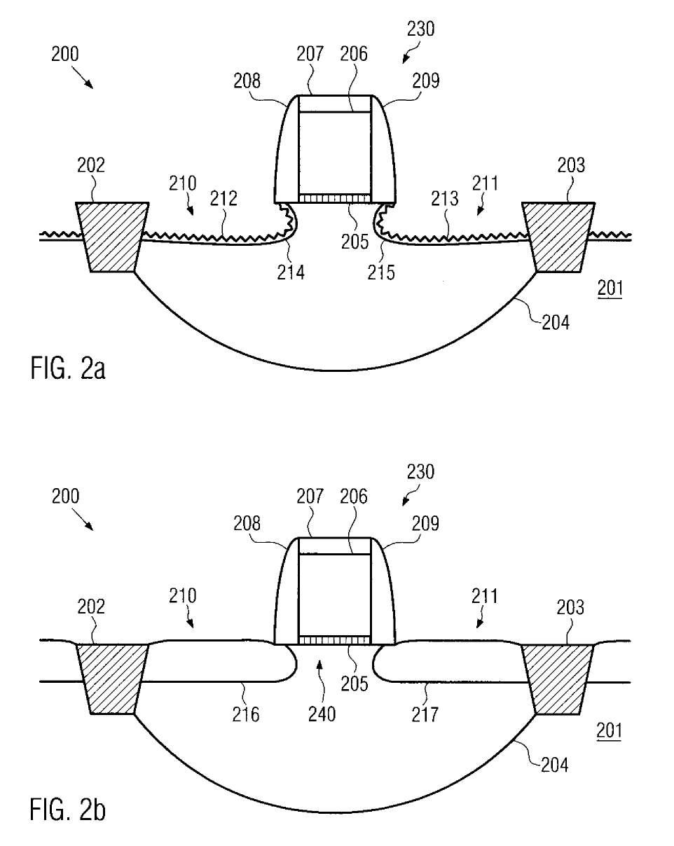

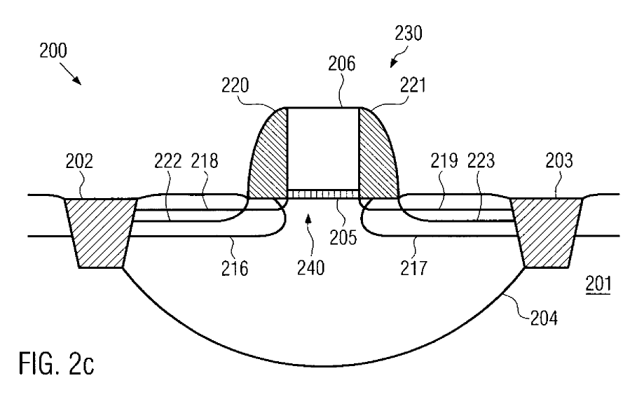

FIG. 2a shows a schematic cross-sectional view of a semiconductor structure 200 in a first stage of a manufacturing process. The semiconductor structure 200 comprises a substrate 201. In the substrate 201, shallow trench isolations 202, 203 and an active region 204 are formed. A gate insulation layer 205 electrically insulates a gate electrode 206 from the substrate 201. The gate electrode 206 is covered by a cap layer 207 and flanked by first sidewall spacers 208, 209. The shallow trench isolations 202, 203, the active region 204, the gate insulation layer 205, the gate electrode 206, the cap layer 207 and the first sidewall spacers 208, 209 may be formed by means of methods of photolithography, etching, deposition and oxidation known to persons skilled in the art.

The substrate 201 and the gate electrode 206 may comprise silicon. For example, the substrate 201 may comprise crystalline silicon and the gate electrode 206 may comprise polysilicon. In some embodiments, the shallow trench isolations 202, 203, the cap layer 207 and the first sidewall spacers 208, 209 can comprise silicon nitride. In other embodiments, these features may comprise silicon dioxide. In still further embodiments, the shallow trench isolations 202, 203, the cap layer 207 and the first sidewall spaces 208, 209 can be formed from different materials. For example, the shallow trench isolations 202, 203 can comprise silicon dioxide and the first sidewall spacers 208, 209 as well as the cap layer 207 can comprise silicon nitride.

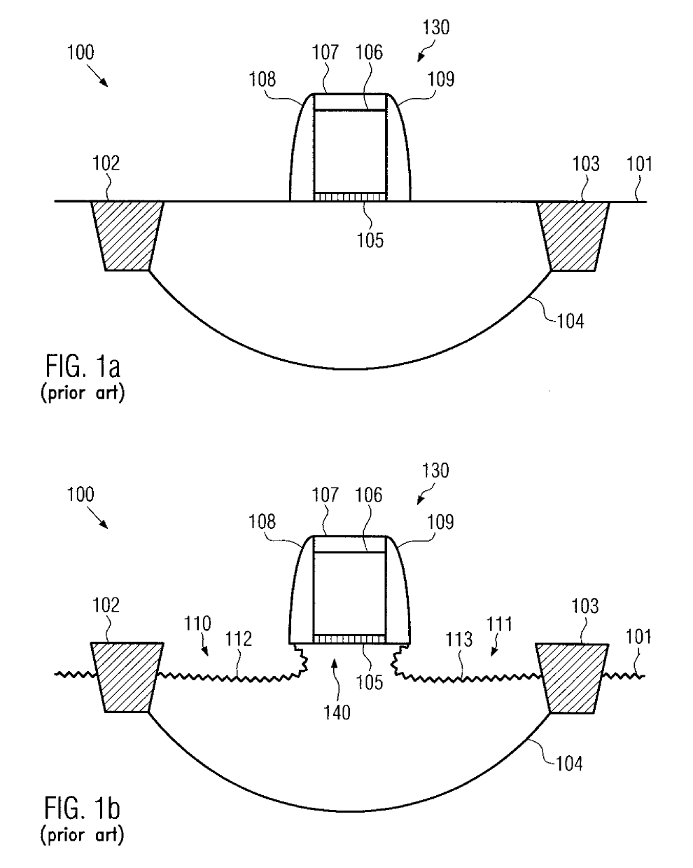

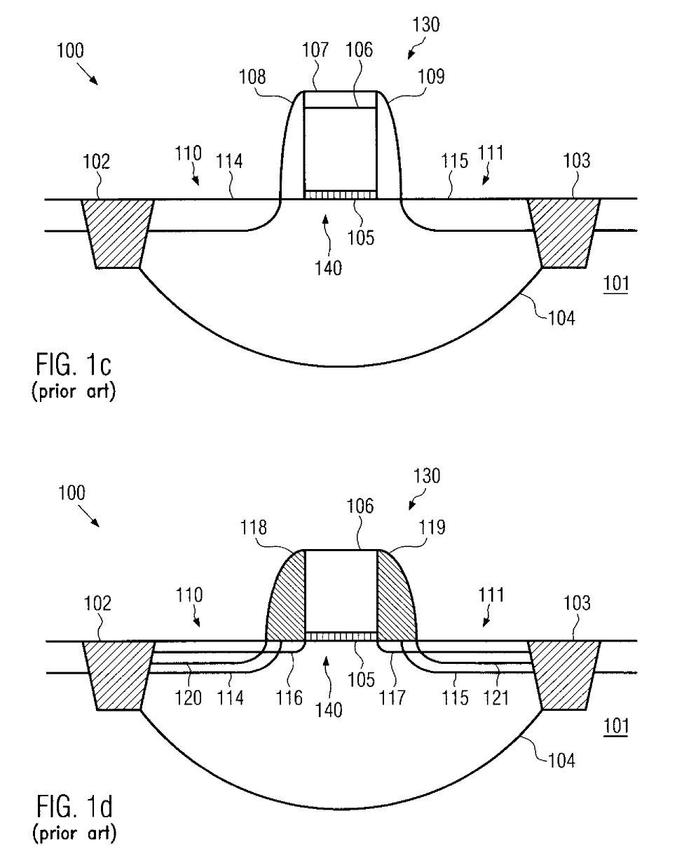

A source side cavity 210 and a drain side cavity 211 are formed in the substrate 201 adjacent the gate electrode 206. Similar to the formation of the cavities 110, 111 in the method of manufacturing a field effect transistor according to the state of the art described above with reference to FIGS. 1a-1d, the cavities 210, 211 can be formed by means of a first etch process which may be isotropic, for example, a dry etch process.

In dry etching, which is also known as plasma etching, reactive ion etching, or ion enhanced etching, a radio frequency glow discharge produces a chemically reactive species such as atoms, radicals, and ions from a relatively inert molecular gas. The etching gas is selected such that a generated species reacts chemically with the material to be etched, creating a volatile reaction product. The energy of ions impinging on the substrate may be controlled by varying the frequency applied in creating the glow discharge and/or applying a DC bias to the substrate. In general, a greater energy of the ions leads to a greater anisotropy of the etch process.

In the first etch process, the semiconductor structure 200 is exposed to an etchant adapted to selectively remove the material of the substrate 201, leaving the gate electrode 206 covered by the first sidewall spacers 208, 209 and the cap layer 207 substantially intact. In embodiments wherein the substrate 201 comprises silicon and the cap layer 207 and the first sidewall spacers 208, 209 comprise silicon nitride and/or silicon dioxide, a selective removal of the material of the substrate 201 may be achieved by using a dry etch process performed by means of an etch gas comprising carbon tetrafluoride (CF₄) and/or oxygen (O₂). The isotropy of the first etch process may be obtained by providing a low DC bias or no DC bias at all.

The present invention is not restricted to embodiments wherein a dry etch process is performed. In other embodiments, the cavities 210, 211 can be formed by means of a wet etch process.

Due to the isotropic nature of the first etch process, portions of the cavities 210, 211 may extend below the first sidewall spacers 208, 209 or even below the gate electrode 206. The surface of the substrate 201 in the cavities 210, 211 may be rough. Reference numerals 212, 213 schematically indicate roughness of the surface 201.

After the first etch process, the surface of the semiconductor structure 200 is exposed to a reactant. The reactant can be a gas. In embodiments wherein the first sidewall spacers 208, 209 and the cap layer 207 comprise silicon nitride, the reactant can comprise oxygen. The oxygen can be provided in elementary form (O₂) and/or in the form of a chemical compound comprising oxygen such as water (H₂O) or nitrogen dioxide (NO₂).

In other embodiments wherein the first sidewall spacers 208, 209 and the cap layer 207 comprise silicon dioxide, the reactant can comprise nitrogen. The nitrogen may be provided in the form of a chemical compound comprising nitrogen such as ammonia (NH₃).

A chemical reaction between the material of the substrate 201 and the reactant is performed. In some embodiments, the chemical reaction between the material of the substrate 201 and the reactant can be initiated by exposing the semiconductor structure 200 to an elevated temperature. In embodiments wherein the reactant comprises oxygen, a thermal oxidation can be performed. In thermal oxidation, the semiconductor structure is exposed to a moderately high temperature while being exposed to the reactant comprising oxygen.

The thermal oxidation can be a rapid thermal oxidation. Rapid thermal oxidation can be performed at a temperature in a range from about 900-1000° C. and may have a duration in a range from about 10 seconds to about 30 seconds. As persons skilled in the art know, in rapid thermal oxidation, the semiconductor structure 200 can be exposed to the moderately high temperature by irradiating the semiconductor structure 200 with electromagnetic radiation. The electromagnetic radiation can be generated by means of one or more lamps and/or a laser.

In other embodiments wherein the reactant comprises nitrogen, a thermal nitridation can be performed. In thermal nitridation, the semiconductor structure 200 is exposed to a moderately high temperature while being exposed to the reactant comprising nitrogen. The thermal nitridation process can be a rapid nitridation process wherein the semiconductor structure 200 is heated by means of radiation generated by one or more lamps and/or a laser.

In other embodiments, the chemical reaction can be initiated by creating a glow discharge in the reactant while the semiconductor structure 200 is exposed to the reactant. To this end, a radio frequency alternating voltage can be applied between a first electrode and the semiconductor structure 200 and/or a second electrode provided in the vicinity of the semiconductor structure 200. In the glow discharge, chemically reactive species such as atoms, radicals and/or ions are created from the reactant. The reactive species then reacts with the material of the semiconductor structure. In embodiments wherein the reactant comprises oxygen, a plasma-enhanced oxidation process may be performed wherein the semiconductor structure 200 is exposed to a gas comprising oxygen, water and/or nitrogen dioxide and a radio-frequency glow discharge is created in the reactant gas. Similarly, in embodiments wherein the reactant comprises nitrogen, a plasma-enhanced nitridation process wherein a radio-frequency glow discharge is created in the reactant gas comprising nitrogen can be performed.

The present invention is not restricted to embodiments wherein the reactant is provided in gaseous form. In other embodiments, the reactant can be provided in liquid form. In such embodiments, the semiconductor structure 200 may be exposed to the reactant by inserting the semiconductor structure 200 into a bath of the liquid reactant. Alternatively, the liquid reactant may be sprayed on the surface of the semiconductor structure 200. The chemical reaction between the reactant and the material of the substrate 201 can be initiated by the contact between the semiconductor structure 200 and the liquid reactant. In one embodiment, the reactant comprises oxygen which is provided in the form of an aqueous solution of hydrogen peroxide (H₂O₂) which may additionally comprise sulphuric acid (H₂SO₄), hydrochloric acid (HCl) and/or nitric acid (NH₃).

In the chemical reaction, a layer 214 of a reaction product is formed on the surface of the source side cavity 210. Similarly, a layer 215 of reaction product is formed on the surface of the drain side cavity 211. The interface between the layer 214, 215 of reaction product and the substrate 211 can be smoother than the surface of the cavities 210, 211. Such smoothing effect may be created by diffusion of the reactant to the interface between the layers 214, 215 of reaction product and the substrate 201, wherein the reactant is distributed over the interface. This may reduce the influence of roughness 212, 213 on the chemical reaction.

The layers 214, 215 of reaction product are selectively removed from the semiconductor structure 200. This can be done by performing a second etch process adapted to selectively remove the layers 214, 215 of reaction product, leaving other features on the surface of the semiconductor structure 200 such as the gate electrode 206 covered by the first sidewall spacers 208, 209 and the cap layer 207 substantially intact. In particular, the second etch process can be adapted to substantially not affect the material of the cap layer 207 and the first sidewall spacers 208, 209. Thus, the cap layer 207 and the first sidewall spacers 208, 209 protect the gate electrode 206 from being affected by an etchant used in the second etch process.

The second etch process can be a wet etch process. In embodiments wherein the reaction product comprises silicon dioxide, the layers 214, 215 of reaction product can be removed by inserting the semiconductor structure 200 into an aqueous solution of hydrofluoric acid (HF). In other embodiments, the second etch process can be a dry etch process. In embodiments wherein the reaction product comprises silicon dioxide, the layers 214, 215 of reaction product can be removed by means of a dry etch process wherein an etching gas comprising carbon tetrafluoride, oxygen and hydrogen is used. In embodiments wherein the reaction product comprises silicon nitride, an etching gas comprising CHF₃, O₂, CH₂F₂ and/or CH₃F may be used.

In the second etch process, the layer 214, 215 of reaction product may be completely removed from the semiconductor structure 200 such that substantially no residues of the layers 214, 215 of reaction product remain on the surface of the semiconductor structure 200.

After the first etch process, the interface between the layers 214, 215 of reaction product and the substrate 201 may be smoother, i.e., less rough, than the surface of the cavities 210, 211. The selectivity of the second etch process tends to avoid roughening the surface of the substrate 201 below the layers 214, 215 of reaction product during the second etch process. Accordingly, the subject matter disclosed herein may be employed to reduce the roughness of the surface of the cavities 210, 211.

During the chemical reaction between the reactant and the material of the substrate 201 wherein the layers 214, 215 of reaction product are formed, the presence of the reaction product may help to reduce a diffusion of atoms of the material of the substrate 201. Therefore, a reduction of the depth of the cavities in the vicinity of the gate electrode 206 and a filling of portions of the cavities 210, 211 extending below the first sidewall spacers 208, 209 and/or below the gate electrode 206 may be reduced compared to the method according to the state of the art described above with reference to FIGS. 1a-1d.

If the chemical reaction between the reactant and the material of the substrate 201 is performed by means of a rapid thermal process such as rapid thermal oxidation or rapid thermal nitridation, the semiconductor structure 200 can be exposed to moderately high temperatures for a shorter time than in the high temperature pre-bake process performed in the method according to the state of the art described above with reference to FIGS. 1a-1d. This may help to further reduce the material transport caused by a diffusion of material of the substrate 201.

A reduction of the material transport caused by a diffusion of substrate material 201 may also be obtained by providing a plasma-enhanced chemical reaction between the material of the substrate 201 and the reactant, since the reactive species created by the electric discharge in the plasma may react with the material of the substrate 201 at relatively low temperatures.

FIG. 2b shows a schematic cross-sectional view of the semiconductor structure 200 in a later stage. Strain-creating elements 216, 217 can be formed adjacent the gate electrode 206. Similar to the strain-creating elements 114, 115 in the method of forming a field effect transistor according to the state of the art described above with reference to FIGS. 1a-1d, the strain-creating elements 216, 217 may comprise a compressively strained material layer comprising silicon germanide which is formed by means of selective epitaxial growth. Other strain-creating materials known to those skilled in the art may also be employed.

Selective epitaxial growth is a variant of plasma-enhanced chemical vapor deposition well known to persons skilled in the art wherein process parameters such as temperature, pressure, and composition of the reactant gas are adapted such that a layer of material is deposited only on the exposed portions of the substrate 201, in particular in the cavities 210, 211, whereas there is substantially no deposition on the shallow trench isolations 202, 203, the cap layer 207 and the first sidewall spacers 208, 209.

In embodiments wherein the substrate 201 comprises silicon and the cap layer 207 and the first sidewall spacers 208, 209 comprise silicon dioxide and/or silicon nitride, dichlorosilane (SiH₂Cl₂) and germane (GeH₄) can be used as reactant gases to form strain-creating elements 216, 217 comprising silicon germanide. Additionally, hydrogen may be provided as a carrier gas and HCl may be supplied in order to increase the selectivity of the epitaxial growth of silicon germanide.

Since the silicon germanide of the strain-creating elements 216, 217 has a greater lattice constant than the silicon of the substrate 201, the strain-creating elements 216, 217 can be compressively strained. The strain of the strain-creating elements 216, 217 may act also on portions of the substrate 201 in the vicinity of the strain-creating elements 216, 217, in particular on portions of the substrate 201 below the gate electrode 206 wherein a channel region will be formed. Thus, the mobility of holes and/or electrons in the channel region can be increased.

The present invention is not restricted to embodiments wherein the strain-creating elements 216, 217 comprise silicon germanide. In other embodiments, the strain-creating elements 216, 217 may comprise silicon carbide. Silicon carbide has a lattice constant which is smaller than the lattice constant of silicon. The silicon carbide in the strain-creating elements 216, 217, however, may adapt to the crystal lattice of the silicon in the substrate 201 such that the strain-creating elements 216, 217 are subject to tensile strain. The tensile strain may influence the strain state of portions of the substrate 201 in the vicinity of the strain-creating elements. Thus, a tensile strain may be created in a channel region 240 below the gate electrode 206. Similar to the strain-creating elements 216, 217 when comprising silicon germanide, the strain-creating elements 216, 217 when comprising silicon carbide can be formed by means of selective epitaxial growth. Selective epitaxial growth of silicon carbide can be effected by creating a radio-frequency glow discharge in a gas comprising silane (SiH₄), ethene (C₂H₄) and hydrochloric acid (HCl).

Since the methods disclosed herein may permit the formation of cavities 210, 211 with a greater depth in the vicinity of the gate electrode 206, and may reduce a transport of material of the substrate 201 into portions of the cavities 210, 211 extending below the first sidewall spacers 208, 209 and/or the gate electrode 206, the strain-creating elements 216, 217 may be provided closer to the channel region 240 and with a greater depth in the vicinity of the channel region 240 than in the method according to the state of the art described above with reference to FIGS. 1a-1d. Therefore, compared to the method according to the state of the art, a greater level of strain and, hence, a greater mobility of holes and/or electrons in the channel region 240 may be obtained.

FIG. 2c shows a schematic cross-sectional view of the semiconductor structure 200 in yet another stage of the manufacturing process. After the formation of the strain-creating elements 216, 217, the first sidewall spacers 208, 209 and, optionally, the cap layer 207 can be removed. This can be done by means of a known etch process adapted to selectively remove the material of the first sidewall spacers 208, 209 and/or the cap layer 207, leaving the materials of the gate electrode 206, the strain-creating elements 216, 217 and the shallow trench isolations 202, 203 substantially intact.

Then, a first ion implantation process wherein ions of a dopant material are introduced into portions of the substrate 201 and/or the strain-creating elements 216, 217 is performed to form an extended source region 218 and an extended drain region 219.

Subsequently, second sidewall spacers 220, 221 can be formed adjacent the gate electrode 206 by means of known methods comprising an isotropic deposition of a layer of spacer material and an anisotropic etch process, and a source region 222 and a drain region 223 may be formed adjacent the second sidewall spacers 220, 221 by means of a second ion implantation process. Finally, an annealing process can be performed in order to activate the dopants introduced into the extended source region 218, the extended drain region 219, the source region 222 and the drain region 223.

The present invention is not restricted to embodiments wherein the first sidewall spacers 208, 209 are removed after the formation of the strain-creating elements 216, 217. In other embodiments, an extended source region similar to the extended source region 218 and an extended drain region similar to the extended drain region 219 can be formed after the formation of the gate electrode 206 and before the formation of the first sidewall spacers 208, 209. During the processes performed in the formation of the cavities 210, 211 and the strain-creating elements 216, 217, the first sidewall spacers 208, 209 protect portions of the extended source region and the extended drain region below the first sidewall spacers 208, 209. Hence, these portions remain in the semiconductor structure 200.

In such embodiments, the material deposited in the formation of the strain-creating elements 216, 217 can be doped while the strain-creating elements are formed. To this end, a chemical compound comprising the dopant material can be added to the gas supplied in the selective epitaxial growth process. In the selective epitaxial growth process, the dopant material is incorporated into the material of the strain-creating elements 216, 217 and doped strain-creating elements 216, 217 are formed. The doped strain-creating elements, together with the portions of the extended source region and the extended drain region under the first sidewall spacers 220, 221, form a source and a drain.

In other embodiments wherein an extended source region and an extended drain region are formed prior to the formation of the strain-creating elements 216, 217, source and drain regions similar to the source region 222 and the drain region 223 can be formed by performing an ion implantation in order to introduce ions of a dopant material into the strain-creating elements 216, 217. The first sidewall spacers 208, 209 may remain on the surface of the substrate 201 during this ion implantation. Thus, the source region and the drain region are spaced apart from the gate electrode 206.

The present invention is not restricted to embodiments wherein a surface roughness of cavities formed adjacent the gate electrode of a field effect transistor is reduced. Instead, the present invention can be applied whenever it is desirable to reduce the roughness of the surface of a semiconductor structure or a portion thereof. For example, the present invention may be applied to reduce the roughness of a semiconductor substrate prior to the formation of any electrical element on the surface thereof.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of reducing a roughness of a surface of a semiconductor structure, comprising:
exposing said surface of said semiconductor structure to a reactant;
performing a chemical reaction between a material of said semiconductor structure and said reactant, a layer of a reaction product being formed on at least a portion of said surface of said semiconductor structure in said chemical reaction;
selectively and completely removing said layer of said reaction product; and
performing a selective epitaxial growth process to deposit a material layer over at least a portion of said surface of said semiconductor structure.

2. The method of claim 1, wherein said reactant is a gas.

3. The method of claim 1, wherein said reaction product comprises an oxide of said material of said semiconductor structure.

4. The method of claim 3, wherein said reactant comprises oxygen.

5. The method of claim 1, wherein performing said chemical reaction comprises performing a thermal oxidation.

6. The method of claim 5, wherein said thermal oxidation is performed at a temperature in a range from about 900-1000° C.

7. The method of claim 5, wherein a duration of said thermal oxidation is in a range from about 10 seconds to about 30 seconds.

8. The method of claim 1, wherein performing said chemical reaction comprises performing a plasma-enhanced oxidation.

9. The method of claim 1, wherein said material of said semiconductor structure comprises silicon.

10. The method of claim 9, wherein said reaction product comprises silicon dioxide and wherein removing said layer of said reaction product comprises inserting said semiconductor structure into an aqueous solution of hydrogen fluoride.

11. A method of forming a semiconductor structure, comprising:
forming a feature on a surface of a substrate;
performing a first etching process adapted to selectively remove a material of said substrate, leaving said feature substantially intact;
after said first etching process, exposing said semiconductor structure to a reactant and performing a chemical reaction between said material of said substrate and said reactant, a layer of a reaction product being formed on at least a portion of said substrate; and
performing a second etching process adapted to selectively remove said layer of said reaction product, leaving said feature and said material of said substrate substantially intact.

12. The method of claim 11, wherein said first etching process is substantially isotropic.

13. The method of claim 11, further comprising depositing a strained material layer adjacent said feature.

14. The method of claim 12, wherein said material of said substrate comprises silicon and said strained material layer comprises silicon germanide.

15. The method of claim 12, wherein said deposition of said strained material layer comprises selective epitaxial growth.

16. The method of claim 11, wherein said feature comprises a gate electrode.

17. The method of claim 11, wherein said layer of said reaction product is completely removed in said second etching process.

18. The method of claim 11, wherein said performing said chemical reaction comprises a rapid thermal oxidation.

19. The method of claim 11, wherein said performing said chemical reaction comprises a plasma-enhanced oxidation.

20. The method of claim 11, wherein said reactant substantially does not react with a material on a surface of said feature.
